(19) United States
(12) Patent Application Publication
(10) Pub. No.: US 2006/0006510 A1
(43) Pub. Date: Jan. 12, 2006

(54) Plastic encapsulated semiconductor device with reliable down bonds

(76) Inventor: Sreenivasan K. Koduri, Plano, TX (US)

Correspondence Address: TEXAS INSTRUMENTS INCORPORATED, P O BOX 655474, M/S 3999, DALLAS, TX, 75265, US

(21) Appl. No.: 10/886,352

(22) Filed: Jul. 6, 2004

(51) Int. Cl. H01L 23/02

(52) U.S. Cl. 257/678

(57) ABSTRACT

Plastic encapsulated semiconductor devices having elevated topographical features on the chip mount pad to control the extent of delamination at the plastic to substrate interface, thereby allowing reliable down bond sites to be formed on the top surface of the chip mount pad which may serve as a ground plane. The cost effective invention is applicable to a variety of semiconductor packages, including both leaded and non-leaded types for high frequency circuits.

### FIELD OF THE INVENTION

The present invention is related to a semiconductor device, and more particularly to a device having reliable down bonds.

### BACKGROUND OF THE INVENTION

Plastic encapsulated semiconductor devices typically include an integrated circuit chip having mechanical and electrical contacts to a substrate which, in turn, provides connections to an electronic system external to the device. Substrates typically are a metallic lead frame or an insulating base having a plurality of patterned conductive leads. Ball grid array (BGA) packages and some chip scale packages (CSP) are examples of the latter substrate type. Among others, packages with lead frames include quad flat packages (QFP), small outline packages (SOP), and J-lead small outline devices (SOJ). Recently, much emphasis has been placed on circuit board space saving devices such as quad flat no lead (QFN), small outline no lead (SON), and other devices having small area of the lead contacts protruding from the package. A typical “no lead package” 10, illustrated in a cross sectional view FIG. 1, includes leads 11 extending slightly past the point where the lead 11 exits the encapsulation 12. The leads are seated at or very near the bottom of the device so that solder 13 from the printed circuit board (PCB) 14 assembly makes contact with the protruding lead 11. The chip 16 is attached to the chip mounting pad 17 by an adhesive and bond wires 15 connect the chip 16 to a portion of the lead inside the encapsulation 12. No lead devices require less board space than their leaded counterparts which have external leads formed outside the package in gull wing or J shapes. Devices having lead frame substrates typically have leads on either two or four sides.

A plastic resin encapsulates the chip mounting pad, the chip, and a plurality of inner leads which includes bonding lands having bond wires connected to the chip. Leads extending outside the encapsulation, hereafter referred to as outer leads, provide contacts with an external electronic system.

Plastic encapsulated packages are generally required to be low cost, but the performance and reliability must meet demanding industry standards. Currently, virtually all types of integrated circuits (IC's) are housed in plastic packages. Many high frequency IC devices avoid the higher cost of multi-layer substrates by using the chip mounting pad itself as a ground plane to which multiple ground contacts are made. Multiple ground connections are formed by bond wires 20 from chip 26 to the chip support pad 27; such connections known as down bonds 20 are illustrated from a top view in FIG. 2a and in a cross section in FIG. 2b. Conventional wire bonds 25 provide signal and other connections between the chip and the inner leads 21.

A frequent reliability issue with plastic encapsulated devices is delamination, most frequently occurring at an interface between the encapsulation and the largest topographically uninterrupted surface of the lead frame or other substrate. A major contributing factor to delamination is the difference in thermal expansion coefficients between materials in the device. The interface between two materials becomes stressed during thermal excursions and once delaminating has been initiated, it progresses rapidly to the contiguous surfaces.

A variety of material, design, and environmental factors contribute to delaminating, but the failure is most pronounced at the interface between the smooth surface of the chip pad and plastic encapsulation. Delamination is particularly worrisome in the case of a large chip pad and smaller chip. A scanning acoustical micrograph of a QFN 31 after thermal stressing provides an example of the delaminated area 30 in FIG. 3. The surface of the chip 36 shows no delamination, but the plastic to chip mount pad 30 interface surrounding the chip has delaminated. Reliable down bonds cannot be made in regions of potential delamination because high levels of stress will be placed on the thin, fragile bond wire.

Thin devices having plastic encapsulation only on one side, such as CSP, QFN, and SON packages are particularly susceptible to delamination because of thermal stresses and substrate distortion. Further, these package types often are used for newer high frequency chips which are small in size, but require multiple down bonds for ground connections.

Grooves 44 formed in chip mount pad 47 and leads 41 have been proposed, as illustrated in FIG. 4. Such grooves may act to interfere with chip adhesive 42 resin bleed, and may provide locking mechanisms for encapsulation 46, but they weaken the substrate, making it more susceptible to warping and consequently to loss of adhesion. Further, this lead frame design includes costly silver spot plating of lands 48 for wire bonds 45.

Other prior attempts to insure adhesion include abrading to roughen and increase the surface area, adding holes or indentations to provide mechanical locking, applying chemical coating to the chip mount pad, or alternately by making formulation changes to the polymeric materials. However, these techniques have resulted in poor compromises, including yield loss due to poor bonding surfaces, cost adders, and degraded reliability.

Not only is the issue of down bonding impacted by delamination between resin encapsulation and substrate, but reliability may also be significantly impacted by moisture ingress into the package. Devices having down bonds require a smooth bondable surface material, typically Au, Pd, or Ag. Moisture and contaminants into the package present problems of current leakage and corrosion of metal conductors on the chip, but in the case of Ag plated leads Ag migration, an issue of by-gone days, may re-emerge.

Therefore, it is most desirable to provide a solution applicable to various semiconductor packages which limits the extent of delamination between the plastic encapsulation and substrate, enables reliable bonds to be made to the chip pad, and does not compromise the package integrity.

### SUMMARY OF THE INVENTION

The plastic encapsulated semiconductor device of the invention includes an integrated circuit chip interconnected by one or more reliable down bond wires to the chip pad substrate and by conventional wire bonds to the leads. The substrate comprises a chip mount pad and leads. The chip mount pad is larger than the chip, includes one or more elevated topographical features, and has one or more bondable sites on the top surface for down bonds. The chip mount pad includes no groove or other indentation, so as to provide a stronger, more distortion free substrate. The conductive leads have lands for bond wire contacts and contacts for external connection. The elevated topographical features on the top surface of the chip mount pad hinder delamination of the plastic from the pad, thereby allowing reliable down bonds to be connected.

In a preferred embodiment, the substrate is a lead frame with raised structures on the top surface of the chip mount pad which provide interruptions to hinder mold compound delamination, serves as a ground plane for reliable down bonds, and add mechanical support to the thin pad structure which, in turn, aids in eliminating package distortion. The device may be a fully encapsulated package such as a QFP, SOP, or SOJ, or it may be a no lead package such as a QFN or SON. Hindering delamination minimizes ingress of moisture and contaminants into the package and supports the use of full lead plating, such as Ni/Pd/Au, rather than more costly spot silver on the bonding areas and a different solderable surface on the external leads.

The lead frame based device of the first embodiment includes elevated features positioned at the perimeter of the chip mount pad provide down bond sites. In other chip mount pad configurations, the elevated features separate the chip area from the down bond sites on the pad. The surface discontinuities on the chip mount pad can be parallel elevated topographical features formed on both sides of a centrally located chip. Other discontinuities in the chip mount pad are in the form of an inverted “V” having the elevation portion on the top of the pad and an indentation in the bottom of the pad.

In another embodiment, the substrate comprises an insulating base, a chip mount pad having elevated topographical features with conductive, bondable surfaces, and a plurality of conductive contact pads and leads. In yet another configuration, elevated structures separate one quadrant of the pad, where the chip resides, from the remainder of the mount pad. Reliable down bonds may be placed in the bondable area separated from the chip. In still another embodiment, one or more elevated topographical features secured to the chip mount pad have bondable surfaces and serve as the down bond lands.

Elevated structures on a chip mount pad are formed in a number of different ways, such as by punching the metal lead frame to cause protrusions, by securing structures by adhesives or welding, or by reverse etching of the pad metal.

Lead frames with unique chip mount pads of the current invention are typically formed of a copper alloy and have a bondable and solderable plated surface, preferably Ni/Pd and/or Ni/Pd/Au. The fully plated lead frames require no spot plating, thereby avoiding added cost to the manufacture and eliminating silver plating inside the package.

The semiconductor device with reliable down bonds may be housed in many different package types; exemplary lead frame based packages are QFP, SOJ, or no lead packages. The device may include an insulating substrate, such as a BGA or CSP having ball contacts on the underside of the package.

### BRIEF DESCRIPTION OF THE DRAWINGS

FIG. 1 illustrates in cross section an existing no lead package attached to a circuit board.

FIG. 2a is a top view of a known semiconductor device having down bonds to a chip pad and bonds to leads.

FIG. 2b is a cross sectional view of a chip with down bonds to a chip pad and bonds to a lead. (Prior art.)

FIG. 3 illustrates a delaminated chip mount pad as detected by scanning acoustical microscopy.

FIG. 4 illustrates a known device having grooves in chip pad and leads.

FIG. 5 is a cross section of one embodiment of the invention, having elevated down bond sites at the perimeter of the chip mount pad.

FIG. 6a is an embodiment wherein wires are bonded to elevated structures on a chip mount pad.

FIG. 6b demonstrates down bonding to an area of the chip mount pad separated by raised structures.

FIG. 7a is a top view of a device having elevated structures at the perimeter of the chip mount pad.

FIG. 7b demonstrates the upward formed chip mount pad.

FIG. 8a is the top view of a device having parallel elevated structures on the chip mount pad.

FIG. 8b shows the cross section of a device having upward protrusions formed in a lead frame chip mount pad.

FIG. 9a illustrates an embodiment having elevated structures to which down bonds are made on two sides of a chip.

FIG. 9b includes a chip on one quadrant having elevated down bond sites on the opposite side of the chip mount pad.

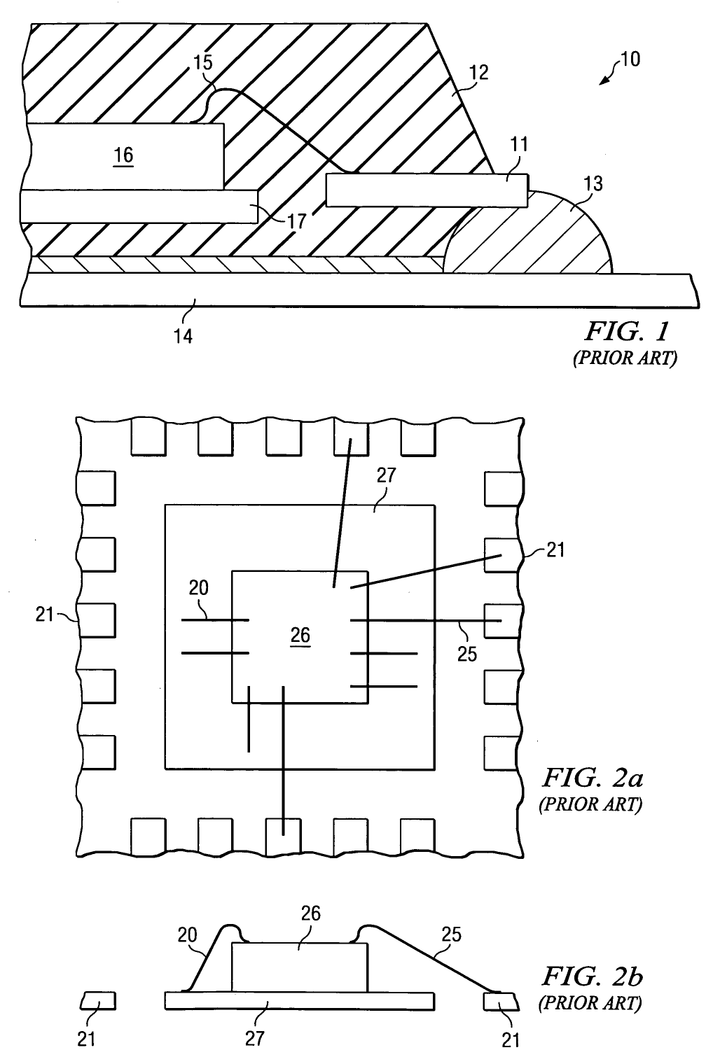

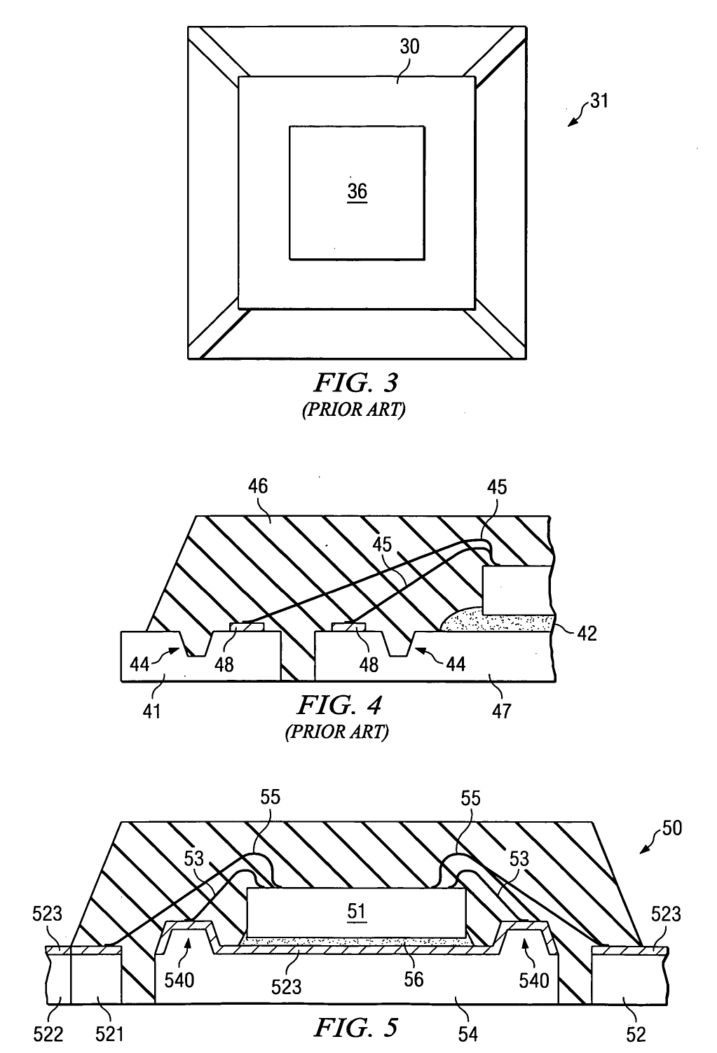

### DETAILED DESCRIPTION OF THE PREFERRED EMBODIMENTS

FIG. 5 illustrates in cross section a semiconductor device 50 having elevated topographical structures 540 formed on the top surface of chip mount pad 54 for the purpose of enhancing adhesion between the encapsulating plastic resin 57 and mount pad 54, thereby allowing bondable areas for reliable down bonds 53 to be provided. Down bonds of gold wires 53 are attached to bondable surfaces on the chip mount pad wherein delamination is controlled. Gold wire bonding to a substrate, known in the semiconductor industry, requires a smooth surface covered by a noble material typically gold, palladium, or silver.

Elevated structures 540 disrupt delamination of the plastic encapsulation to chip mount interface without the need for grooves or other indentations which may increase substrate distortion and further increase stresses at the interface, thus placing unacceptable high levels of stress on the wire bond. Height of the elevated structures is in the range of 5 to 25 microns and the specific height is a function of the substrate composition.

Signal and other contacts are electrically connected by conventional bond wires 55 to inner leads 521. Chip mount pad 54 preferably includes one or more conductive areas which serve as a ground plane. In the preferred embodiment, device 50 comprises an integrated circuit chip 51 having one or more wire bonds 53, hereafter referred to as down bonds, contacting a conductive chip mount pad 54 of a lead frame. The lead frame further includes a plurality of leads 52 comprising inner leads 521 and outer leads 522. Each inner lead 521 includes a landing area for conventional bond wire 55 connections. The outer portion 522 of each lead protrudes outside the plastic encapsulation to allow contact with an external electronic device, such as a printed circuit board (PCB). Preferably, all lead frame surfaces are plated with a material such Ni/Pd or Ni/Pd/Au which is compatible both with gold wire bonds and with solder. The plating layer 523 covers both the chip mount pad 54 and all leads 52. An adhesive 56 mechanically attaches the chip 51 to the chip pad 54.

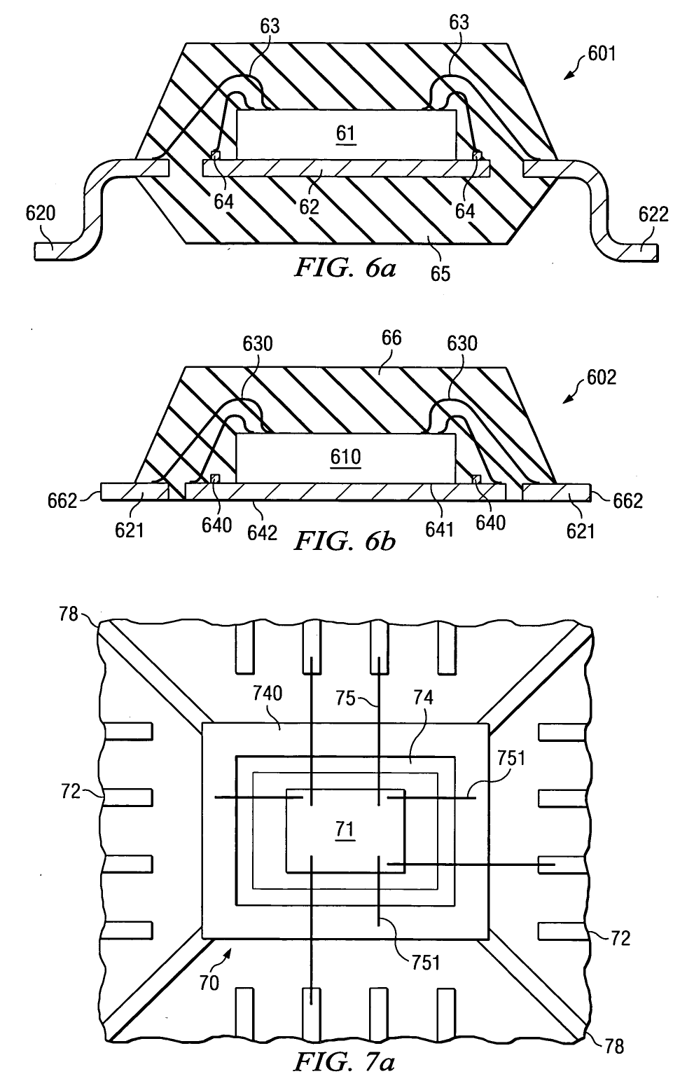

An embodiment of the device 601 in FIG. 6a having elevated features 64 on the top surface of chip mount pad 62 has a lead frame substrate with formed outer leads 622, such as a QFP, SOP, SOJ or other leaded package. Device 601, in FIG. 6a, is fully encapsulated in a plastic molding compound 65. Encapsulation 65 covers the bottom of chip pad 62, chip 61, bond wires 63, and inner leads 620.

Alternately as shown in FIG. 6b, device 602 is a no lead assembly having outer leads 662 severed near the point of egress from the encapsulation 66. Encapsulation 66 of device 602, in FIG. 6b, may cover only chip 610, bond wires 630, inner leads 621, and top 641 of the chip mount pad. The bottom 642 of the chip mount pad is exposed, as is typical of many no lead and high power packages which are soldered directly to an external heat sink.

Configuration of the elevated features 64, 640, 540 and the down bond sites of the devices in FIGS. 5, 6a and 6b are interchangeable; down bonds are made to the top surface of the elevated structure 540 in FIG. 5 and 64 in FIG. 6a, and to the chip mount pad between the elevated structure 640 and the pad perimeter in FIG. 6b.

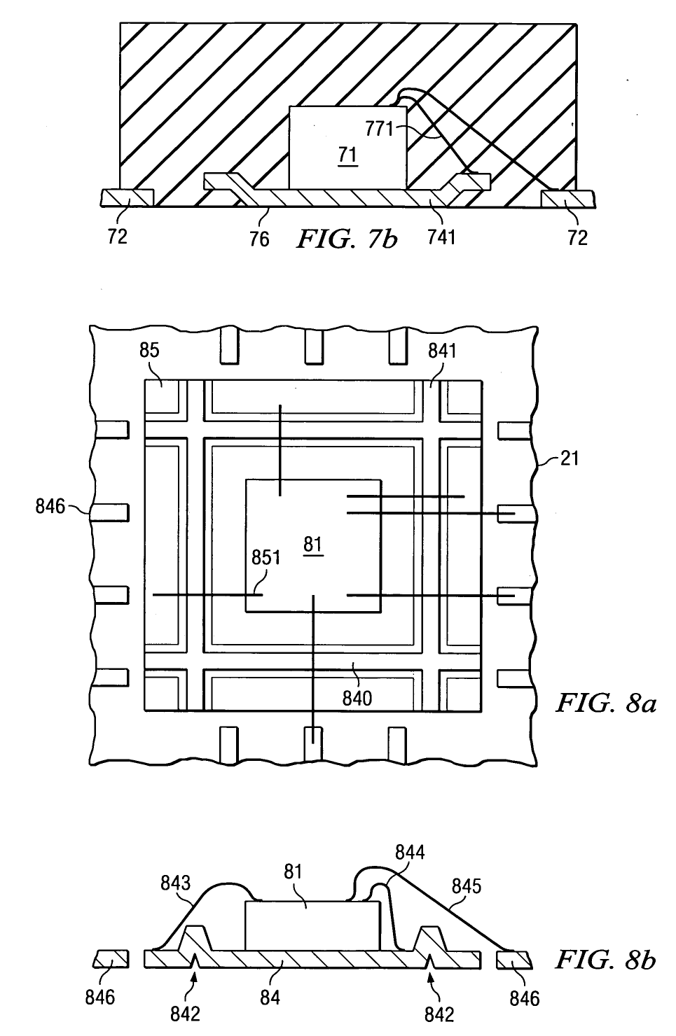

Alternate embodiments of a semiconductor device having sites to which reliable down bond can be made include various designs of elevated structures on the chip mount pad. The preferred configuration, illustrated in FIGS. 5 and 7a, includes a raised platform 740 at the perimeter of the chip mount pad 54, 70 to which multiple down bond wires 53, 751 are attached. The elevated structure 540 and 740 are the landing sites for down bonds to the chip mount pad which serves as a ground plane, adds stability and strength to the chip mount pad 54, 70, and provides a nonuniform surface at the mold compound to chip pad interface. Nonuniformity in the chip mount pad surface limits the extent of potential delaminating and aids in forming a barrier to moisture ingress. Elevated structures on the mount pad add rigidity and control distortion in thin substrates, whereas grooves or other indentations in the substrate are subject to greater distortion.

Conventional bond wires 75 connect chip 71 to the inner leads 72 and down bond wires 751 connect the chip to the elevated structure 740 on chip mount pad 70.

The preferred embodiment of device 50 shown in cross sectional view in FIG. 5 and in a top view in FIG. 7a having raised structure 540, 740 at the perimeter of chip mount pad 54 has a lead frame substrate. However, the configuration with raised structures at the chip mount pad perimeter is applicable to either a lead frame or an insulating substrate device. In the case of a lead frame, the elevated structure 540, 740 preferably is formed by a punching process during lead frame fabrication, or by etching to thin the center of the mount pad. In the case of an insulating substrate with patterned metallization on the leads 52 and chip mount pad 54, the elevated structures 540 preferably are formed either by adhering the structure with a bondable surface to the perimeter of a flat chip pad 54 or by plating.

In the lead frame embodiment support tie straps 78 in FIG. 7a are attached directly to the chip mount pad 70 at each corner. In a no lead package embodiment, the tie straps 78 are severed along with the leads and provide an external contact for the chip pad ground plane. Alternately, external ground contact can be made by wires bonded between the down bond site and one or more leads.

A lead frame substrate embodiment, illustrated in FIG. 7b, demonstrates that the perimeter 761 of the chip mount pad 76 may be formed upwards and flattened prior to plating with a bondable material such as Ni/Pd/Au or Ni/Pd. Down bond wires 771 are made to the elevated portion of the pad 761. Forming by the lead frame manufacturer provides a low cost fabrication technique and requires no changes to the device assembly process. This configuration is particularly compatible with no lead packages such as QFN and SON and with power packages wherein the pad 76 is soldered to a PCB heat sink. The continuous chip mount pad 76, lacking grooves or locking indentations which may increase susceptibility to distortion is advantageous to these direct mount devices.

In FIG. 8a, an alternate configuration of the elevated structures 840 includes parallel ridges which extend the length and/or width of the chip mount pad 85. Down bond wires 851 from the chip 81 can be made to the portion of the pad 841 between the ridges 840 and the pad perimeter. Ridges 840 can be formed in the pad 84 of those materials having sufficient malleability and ductility. Ridges 840 on the top surface of the substrate add strength and stability to the chip mount pad and provide an interruption to resin delamination or moisture ingress.

Ridge shaped elevated structures 840 can be secured to a substrate by an adhesive, by metal to metal bonding or welding, or by an increased plating thickness. The configuration having plated structures is particularly applicable to insulating substrates with metallized leads and down bond lands.

FIG. 8b shows a cross section of inverted “V” shaped ridges 842 formed in the chip pad 84 of a lead frame. The inverted “V” shaped protrusions 842 form an irregular surface on both the top and bottom of the chip pad 84 and provide interruption to plastic delaminating on both surfaces. This lead frame configuration is particularly applicable to a fully encapsulated lead frame based device, such as a QFP or SOJ. Down bond wires 843,844 can be attached to the chip mount pad 84 on either side of the ridge 842. Signal and other bond wires 845 are connected to the leads 846.

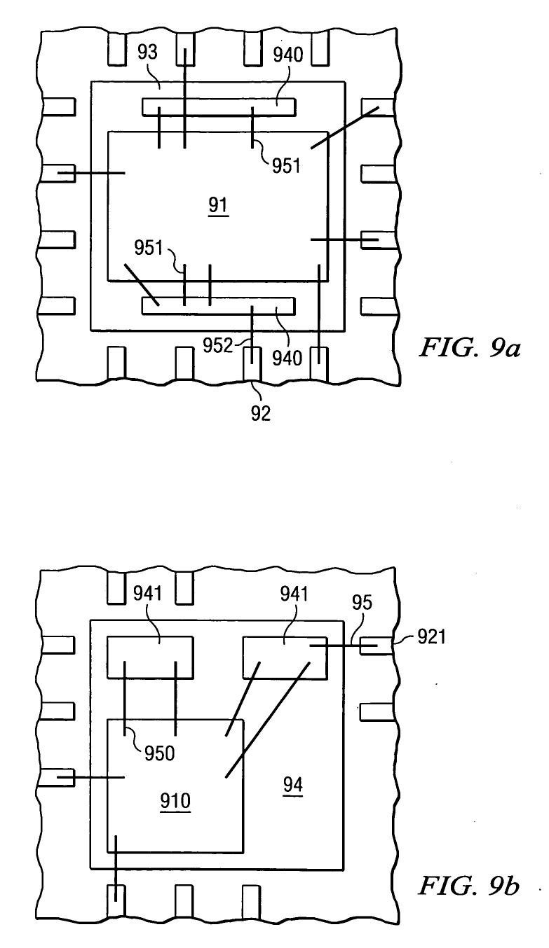

In FIG. 9a, down bond wires 951 are attached to rectangular elevated structures 940 having a conductive bondable surface. One or more of such structures 940 are secured on the chip mount pad 93 in close proximity to a centrally located chip 91. In FIG. 9b, the chip 910 is positioned in one quadrant of the chip mount pad 94 and elevated down bond structures 941 are placed on the opposite side of the chip pad. Multiple down bond wires 950, 951 can be made to bondable, conductive surfaces of the elevated structures 940, 941 as illustrated in FIGS. 9a and 9b. The elevated structures 940, 941 subsequently are connected to an external lead 92, 921 by wire bonds 95, 952. The configurations illustrated in FIGS. 9a and 9b are particularly well suited to a device having an insulating substrate, such as a BGA or CSP device with patterned and plated metal leads, and bonding surfaces. The elevated structures 940, 941 which serve as down bond lands are formed by plating or by adhering a conductor to the upper surface of a chip mount pad.

A lead frame embodiment of the devices illustrated in FIGS. 9a and 9b preferably is formed by patterning and etching a relatively thick lead frame material to form the elevated structures 940, 941, or by metal to metal bonding.

It can be seen from the detailed discussions of FIGS. 5 through 9 that devices having elevated structures on the chip mount pad which interrupt delamination of the plastic encapsulation from the substrate without weakening the substrate can provide reliable down bond sites for various package types. The preferred embodiments having elevated structures around the perimeter of a lead frame chip mount pad as illustrated in FIGS. 5, 7a, and 7b are well suited for no lead and high power packages where the pad of a lead frame is in contact with a board or other external heat sink, as are the embodiments illustrated in FIGS. 6b and 8a. Fully encapsulated lead frame devices such as QFP or SOJ are amenable to the configurations illustrates in FIGS. 5, 6a, 6b, 7a, 8a, and particularly 8b. The device illustrated in FIG. 8b includes irregular topography on both the upper and lower surfaces of the lead frame making it well suited for fully encapsulated devices, such as QFP and SOP. Those devices having conductive bonding lands secured to the upper surface, as in FIG. 9a and 9b are readily adapted to packages having an insulating substrate, such as BGA or some CSP devices. Preferably in each embodiment the down bonds connect to a ground plane of the substrate and in turn are connected to the next level of interconnection either by wire bonds to a lead or by the tie strap of the chip mount pad.

The afore mentioned embodiments provide examples of a multiplicity of device and substrate designs applicable for reliable down bonds which support improved electrical characteristics of integrated circuits, in particular high frequency devices requiring multiple contacts to a ground plane. The various designs support the need not only for reliable down bonds, but also for low cost ground planes. Devices having improved adhesion at the interface between the resin encapsulation and the substrate by elevated structures decrease the probability of distortion and stress on the down bonds and of moisture ingress into the package, thereby assuring overall improved reliability under environmental and operating stresses.

Further, those devices having lead frame substrates are amenable to uniform plating of a material compatible with both wire bonding and soldering, such as Ni/Pd or Ni/Pd/Au, and do not necessitate the use of costly selective plating.

The invention is not limited to these exemplary embodiments, but instead can be practiced in a variety of semiconductor device configurations.

A lead frame having a plurality of conductive leads and a groove free chip mount pad with one or more elevated topographical structures and one or more bondable areas on or above the chip mount area on the top surface of the pad is claimed. The lead frame preferably comprises an alloy of copper having a plated surface. The preferred plating is Ni/Pd or Ni/Pd/Au covering the entire surface, but other plating materials such as spot silver on the bonding areas are included. Height of the elevated structures is in the range of 15 to 50 microns.

An insulating base substrate, preferably comprising a film of the polyimide family, such as Kapton or Upilex, or a composite material, such as FR-5, includes a groove free chip mount pad having one or more elevated topographical structures and one or more bondable conductive areas on the top surface and a plurality of patterned and plated leads. Thickness or height of the elevated structures is in the range of 5 to 25 microns.

What is claimed is:

1. A semiconductor device comprising:
a substrate including a chip mount pad having a planar surface and a plurality of conductive leads;
an integrated circuit chip attached by an adhesive to said chip mount pad surface, said chip having a plurality of contact pads and bond wires connected to said contact pads;
said chip mount pad having a uniform thickness, except for one or more elevated structures extending from the plane whereon said chip is adhered, said structures spaced apart from said chip;
said bond wires connected to said chip mount pad to form down bonds, and one or more wires connected to said leads; and
an insulating resin encapsulation covering said chip, said wires and said substrate.

2. A device according to claim 1 wherein said conductive leads on said chip mount pad form one or more ground planes.

3. A device according to claim 1 wherein said substrate comprises a metal lead frame.

4. A device according to claim 3 wherein said elevated structures include a bondable surface and are positioned near the perimeter of said chip mount pad.

5. A device according to claim 3 wherein a plated film comprising Ni/Pd or Ni/Pd/Au covers said lead frame chip mount pad and lead surfaces.

6. A device according to claim 3 wherein the chip mount pad includes an inverted “V” shaped protrusion.

7. A device according to claim 3 wherein the perimeter of said chip pad is formed upwards and the surface flattened to provide a wire bondable area.

8. A device according to claim 3 wherein said device is fully encapsulated and has protruding external leads.

9. A device according to claim 3 wherein said encapsulation covers the chip, bond wires and top surface of the chip mount pad and inner leads.

10. A device according to claim 1 wherein said elevated structures are parallel upward protrusions near a centrally located chip.

11. A device according to claim 1 wherein down bond wires are connected to a conductive top surface of said elevated structures.

12. A device according to claim 1 wherein said elevated structures are 5 to 40 microns in height above the plane of said chip mount pad.

13. A device according to claim 1 wherein said substrate comprises an insulating base, a plurality of conductive leads, and a groove free chip mount pad with one or more elevated structures having a bondable surface on the top of said substrate.

14. A device according to claim 1 wherein said device is assembled in BGA or CSP package.

15. A device according to claim 1 wherein wire bondable areas on the chip mount pad are connected to a lead or tie strap.

16. A device according to claim 1 wherein said chip is positioned in one quadrant of said chip mounting pad and one or more elevated structures are positioned in the diagonally opposite quadrant.

17. A lead frame comprising an alloy of copper having a plurality of leads and a groove free chip mount pad with one or more elevated structures and one or more bondable areas on the upper surface.

18. A lead frame according to claim 17 wherein the perimeter of said chip mounting pad is formed to be positioned above the plane of the pad and is flattened to form a bondable elevated structure.

19. A lead frame according to claim 17 wherein an inverted “V” is formed into said chip mount pad as an elevated structure on the top surface and an indentation on the back surface.

20. A semiconductor package substrate comprising an insulating base with a plurality of patterned and plated leads and a chip mount pad having one or more elevated structures having a bondable conductive surface.
